(19) United States
(12) Patent Application Publication
(10) Pub. No.: US 2022/0159871 A1
(43) Pub. Date: May 19, 2022

(54) U-SHAPED COOLING MODULE FOR A POWER ELECTRICAL APPARATUS

(71) Applicant: Valeo Siemens eAutomotive France SAS, Cergy (FR)

(72) Inventors: Aurelien Pouilly, Cergy (FR); Alexandre Legendre, Cergy (FR)

(73) Assignee: Valeo Siemens eAutomotive France SAS, Cergy (FR)

(21) Appl. No.: 17/455,271

(22) Filed: Nov. 17, 2021

(30) Foreign Application Priority Data
Nov. 18, 2020 (FR) 2011831

(51) Int. Cl. H05K 7/20; H02M 7/00

(52) U.S. Cl. CPC H05K 7/20272; H05K 7/2089; H02M 1/327; H05K 7/20281; H02M 7/003

(57) ABSTRACT

The invention relates to a cooling module (1), configured to cool at least one electrical module, the cooling module (1) comprising two fluid inlet/outlet orifices (12), and a cooling channel (11) formed in the cooling module (1). The cooling channel (11) has a U-shaped section forming two branches such that said cooling channel (11) ensures U-shaped circulation of the cooling fluid between the two fluid inlet/outlet orifices (12), the cooling module (1) comprising at least one housing (13), between the two branches, which is suitable for allowing the sealed insertion of said at least one electrical module, so as to cool said at least one electrical module by thermal conduction.

### TECHNICAL FIELD

The present invention relates to the field of the cooling of electrical apparatuses, in particular for vehicles, in particular for electric or hybrid vehicles. More specifically, the present invention relates to a cooling module, in particular for a power electrical apparatus, in particular a DC-to-DC voltage converter, an electrical charger, or an inverter.

As is known, a power electrical apparatus can comprise at least one power electronic module. It is specified that the term “power electronic module” is understood to mean an assembly comprising components through which electrical energy flows. These components can comprise electronic switches, such as for example semiconductor transistors, arranged in an electrical circuit so as to allow a controlled flow of electrical energy. In particular, the components are bare semiconductor chips for which a single body realizes encapsulation, such as physical packaging. In other words, a power electronic module is an assembly comprising a plurality of semiconductor chips forming an electrical circuit that are encapsulated in a single package.

Furthermore, according to the prior art, an electric or hybrid vehicle comprises a fluid cooling circuit configured to route a cooling fluid, in particular liquid water, near electrical apparatuses to be cooled, in particular the power electrical apparatuses. Specifically, effective cooling makes it possible in particular to improve the compactness of the power electrical apparatuses.

To this end, a cooling system is used to cool each of the power electrical apparatuses and generally has to satisfy numerous constraints in terms of size, accessibility and cooling effectiveness.

By way of example, the document US 2018219488 A1 describes a power electrical apparatus comprising such a cooling system, a chassis, and a plurality of electrical components to be cooled. The cooling system described by the document US 2018219488 A1 comprises two cooling modules providing four main heat exchange surfaces, in order to cool the plurality of electrical components effectively.

However, the chassis described by the document US 2018219488 A1 comprises channels formed in the mass of the chassis that are configured to fluidly connect the two cooling modules, making the production of such a chassis complex and expensive. Specifically, the implementation of such a chassis entails an expensive moulding technology, in particular a gravity casting process with the use of cores, and entails carrying out a large proportion of the tests, in particular leak tests, at the end of the process for manufacturing the power electrical apparatus, and this is expensive in the event of failure of said leak tests. In addition, the gravity casting process with the use of cores can generate impurities on the surface of the moulded parts, it being possible for the impurities to degrade the performance of the systems comprising these moulded parts.

Furthermore, systems for cooling power electrical apparatuses entail the use of a plurality of seals. It is desirable to reduce the sealing zones as much as possible in order to reduce the likelihood of the cooling fluid leaking.

In order to at least partially overcome these drawbacks, it is desirable for the cooling system to ensure effective cooling of the power electronic modules, while at the same time having a limited set of zones to be sealed so as to reduce the risks associated with a leak of cooling fluid. In addition, it is desirable for the cooling system to be compatible with a manufacturing process with a high production rate, and/or a low industrial manufacturing cost.

The invention thus proposes a U-shaped cooling module configured to cool electrical modules and in particular power electronic modules.

### PRESENTATION OF THE INVENTION

More specifically, the invention relates to a cooling module, configured to cool at least one electrical module, in particular intended to be installed on board an electric or hybrid motor vehicle. The cooling module comprises two fluid inlet/outlet orifices, and a cooling channel formed in the cooling module. The two fluid inlet/outlet orifices respectively convey and discharge a cooling fluid into and from the cooling module. Said cooling channel has a U-shaped section forming two branches, the one and the other of the two fluid inlet/outlet orifices respectively terminating in the one and the other of the two branches, such that said cooling channel ensures U-shaped circulation of the cooling fluid between the two fluid inlet/outlet orifices, the cooling module comprising at least one housing between the two branches that is suitable for allowing the sealed insertion of said at least one electrical module, so as to cool said at least one electrical module by thermal conduction by means of mechanical contact realized respectively between each branch of the cooling module and two opposite external faces of said at least one electrical module.

Thus, the present invention has the substantial advantage of having improved cooling effectiveness by offering four heat exchange surfaces, of which two are intended to cool said at least one electrical module on two external faces that are opposite one another by thermal conduction.

Advantageously, the cooling module comprises a main body, an upper plate, and a lower plate. The main body has a substantially H-shaped section and comprises a central portion, an upper external face, and a lower external face, the main body being substantially open on each of the upper external face and lower external face, the upper plate and the lower plate coming respectively against the upper external face and against the lower external face, such that free volumes respectively delimited by the central portion and the upper plate, and by the central portion and the lower plate, respectively define the one and the other of the two branches of the cooling channel. Such a configuration makes it possible to limit the machining operations and to use simple casting processes that are compatible with a high production rate for the manufacture of the cooling module.

Advantageously, the cooling module comprising an internal plate, the central portion comprises one or a plurality of cutouts formed in the central portion and a shoulder surface coupled to the cutout or the plurality of cutouts, the shoulder surface extending in part around the periphery of the central portion, the internal plate coming to bear against the shoulder surface in a sealed manner so as to form said at least one housing between the central portion and the internal plate.

Advantageously, the central portion comprises internal pillars such that said at least one housing comprises a number of housings that are separated from each other by the internal pillars.

Advantageously, the number of housings is equal to three.

Advantageously, said at least one housing is a through-housing.

Advantageously, the main body consists of a part that is moulded, in particular by a process of sand casting or high-pressure moulding.

According to one embodiment of the invention, the invention relates to an electrical assembly comprising at least one electrical module, and the cooling module.

According to another embodiment of the invention, the invention relates to a power electrical apparatus, in particular configured to be installed on board an electric or hybrid vehicle, comprising the electrical assembly, said at least one electrical module consisting of a plurality of power electronic modules, said power electrical apparatus forming an inverter, a DC-to-DC voltage converter, or an electrical charger.

According to one aspect of the invention, the invention relates to a method for manufacturing an electrical assembly comprising at least one electrical module and a cooling module comprising a cooling channel having a U-shaped section forming two branches, at least one housing, a main body, an upper plate, a lower plate, and an internal plate, the main body having a substantially H-shaped section and comprising a central portion, an upper external face, and a lower external face, the central portion comprising a shoulder surface, the method comprising the following successive steps:
moulding and machining the main body;
laterally inserting each of said at least one electrical module into each housing of said at least one housing;
fastening the internal plate in a sealed manner against the shoulder surface in order to close said at least one housing;
fastening the upper plate, and the lower plate respectively against the upper external face and against the lower external face of the main body so as to respectively form each of the two branches of the cooling channel.

### PRESENTATION OF THE FIGURES

The invention will be better understood upon reading the following description, which is given by way of example, and referring to the following figures, which are given by way of non-limiting examples, in which identical references are given to similar objects:

FIG. 1 represents a view of a cooling module according to the invention;

FIG. 2 represents a sectional view of the cooling module according to the invention;

FIG. 3 represents an exploded view of the cooling module according to the invention.

It should be noted that the figures explain the invention in detail in order to implement the invention, it being of course possible for said figures to serve to better define the invention if necessary.

### DETAILED DESCRIPTION OF THE INVENTION

The invention relates to a cooling module, configured to cool at least one electrical module, and in particular intended to be installed on board an electric or hybrid motor vehicle. The assembly comprising the cooling module and said at least one electrical module will be referred to as electrical assembly. In addition, the invention will be described below in the context of the electrical assembly configured to be incorporated in a power electrical apparatus, in particular an inverter, an electrical charger, or a DC-to-DC voltage converter. In this context, said at least one electrical module corresponds in particular to a plurality of power electronic modules. However, this does not constitute a limitation to this particular application.

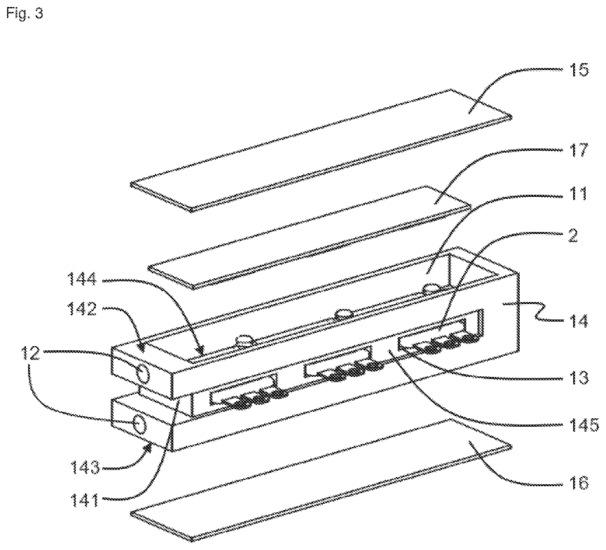

With reference to FIGS. 2 and 3, the cooling module 1 according to the invention comprises two fluid inlet/outlet orifices 12 and a cooling channel 11 formed in the cooling module 1. The two fluid inlet/outlet orifices 12 are configured to respectively convey and discharge a cooling fluid into and from the cooling module 1. The cooling fluid consists generally of liquid water.

In addition, the cooling channel 11 has a U-shaped section forming two branches. The one and the other of the two fluid inlet/outlet orifices 12 open respectively into the one and the other of the two branches. Thus the cooling channel 11 ensures U-shaped circulation of the cooling fluid between the two fluid inlet/outlet orifices 12. Consequently, the cooling module 1 has at least four main heat exchange surfaces defined by two opposite sides of each of the two branches. The cooling module 1 can in particular have five heat exchange surfaces, including the outer lateral surface of the part forming the junction between the one and the other of two branches of the cooling channel 11.

The two fluid inlet/outlet orifices 12 are preferably positioned along the axis respectively of each of the two branches. Another possible configuration is to position the two fluid inlet/outlet orifices 12 perpendicular to the axes respectively of each of the two branches. The two fluid inlet/outlet orifices 12 are preferably located on the same face of the cooling module 1 in order to simplify the arrangement of the cooling module 1 in the power electrical apparatus.

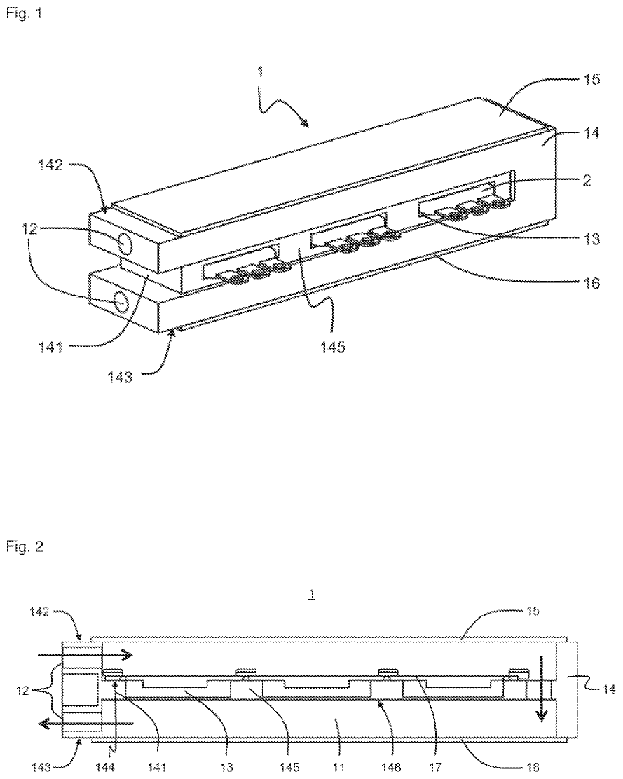

As illustrated in FIGS. 1 to 3, the cooling module 1 comprises at least one housing 13 between the two branches. Said at least one housing 13 is suitable for allowing the sealed insertion of said at least one electrical module 2. In other words, said at least one housing 13 is suitable for allowing the insertion of said at least one electrical module 2, while at the same time allowing sealing of the electrical module 2 with respect to the cooling channel 11. Thus, said at least one electrical module 2 is cooled by thermal conduction by means of mechanical contact realized respectively between each branch of the cooling module 1 and two opposite external faces of said at least one electrical module 2. Such a cooling configuration has improved cooling effectiveness compared with a cooling configuration in which only one face of said at least one electrical module 2 is cooled at a time. In other words, two surfaces, of the four main heat exchange surfaces of the cooling module 1, cool said at least one electrical module 2.

In addition, the sealed nature of said at least one housing 13 makes it possible to insert an electrical module therein that is not necessarily sealed, thus reducing the associated costs. The electrical module is for example a standard electrical module formed by an epoxy moulding of the TML type, which stands for “Transfer Moulded Leadframe”.

It is preferably possible to have a thermal interface material (TIM) between said at least one electrical module 2 and the cooling module 1, in particular on one or both external faces of said at least one electrical module 2 in contact with the cooling module 1. Thus, the contact surface area between said at least one electrical module 2 and the cooling module 1, and consequently the effectiveness of cooling by thermal conduction of said at least one electrical module 2, is improved.

Furthermore, with reference to FIGS. 1 to 3, the cooling module 1 can comprise a main body 14, an upper plate 15, and a lower plate 16. The main body 14 has in particular a substantially H-shaped section. The main body 14 comprises a central portion 141. The central portion 141 corresponds to the central segment connecting the two branches of the substantially H-shaped section. The H-shaped section is taken in a plane transverse to the direction of extension of the cooling channel 11. In particular, the substantially H-shaped section is dimensioned depending on the desired cooling effectiveness for the cooling module 1 and the desired pressure drop values in the fluid system.

In addition, the main body 14 comprises in particular an upper external face 142, and a lower external face 143, such that the main body 14 is substantially open on each of the upper external face 142 and lower external face 143. The upper plate 15 and the lower plate 16 then come respectively against the upper external face 142 and against the lower external face 143. Thus, free volumes respectively delimited by the central portion 141 and the upper plate 15, and by the central portion 141 and the lower plate 16, respectively define the one and the other of the two branches of the cooling channel 11.

The manufacture of a main body 14 having a substantially H-shaped section, and of the upper plate 15 and lower plate 16 as are described above, is simpler to realize than the manufacture of the cooling module 1 as a one-piece part. The main body 14 is in particular formed in one piece. In general, the manufacturing process results from a compromise between the various types of processes, in particular casting, forming, machining, and assembly in order to reduce the manufacturing cost as much as possible and increase the production rate. In particular, a main body 14 as described makes it possible to limit the machining operations and to use simple casting processes that are compatible with a high production rate. The main body 14 can in particular consist of a part that is moulded by a process of sand casting or high-pressure moulding. In addition, the upper plate 15, lower plate 16, and internal plate 17 can be manufactured using a stamping process.

Furthermore, the central portion 141, as defined above and with reference to FIGS. 2 and 3, comprises one or a plurality of cutouts formed in the central portion 141 and a shoulder surface 144 coupled to the cutout or the plurality of cutouts. The shoulder surface 144 extends in part around the periphery of the central portion 141. In order to isolate said at least one housing 13 from the cooling channel 11 in a sealed manner, the cooling module 1 can then comprise an internal plate 17 coming to bear in a sealed manner against said shoulder surface 144. Thus, the one or more free volumes, between the central portion 141 and the internal plate 17, form said at least one housing 13.

The use of the internal plate 17 also makes it possible to simplify the method for manufacturing the electrical assembly comprising the cooling module 1 and said at least one electrical module 2.

The internal plate 17 preferably comprises sealing means, in particular a seal, in order to establish sealing between the cooling channel 11 and said at least one housing 13. The sealing can also be established by the assembly means in the case in which the FSW (“Friction Stir Welding”) welding technique is used.

In addition, with reference to FIG. 2, the upper plate 15, lower plate 16, and internal plate 17, and also a face 146 of the main body 14 can comprise shapes or protuberances that are directed towards the inside of the cooling circuit 11, for the purposes of heat dissipation. For example, it is possible to use protuberances in the form of fins or spikes. Thus, the cooling flows are disturbed and the heat dissipation of the assembled components is improved.

With reference to FIGS. 1 to 3, the central portion 141 can comprise internal pillars 145 such that said at least one housing 13 comprises a number of housings that are separated from each other by the internal pillars 145. The internal pillars 145 in particular form the crossbar of the H shape. The number of housings corresponds in particular to the number of electrical modules of said at least one electrical module 2. The number of housings can in particular be equal to three. In other words, two internal pillars are necessary in order to form the three housings.

The use of internal pillars 145 advantageously contributes to the mechanical strength of the cooling module 1. In addition, the internal pillars 145 make it possible to reinforce the control, more precisely than in the absence of internal pillars, of the flatness of the shoulder surface 144. Controlling the flatness of the shoulder surface 144 involves controlling the thickness of thermal interface material disposed between said at least one electrical module 2 and the internal plate 17. The more the thickness of the thermal interface material is reduced, the more effective the cooling of said at least one electrical module 2 by thermal conduction. This improves the cooling effectiveness of the cooling module 1.

In addition, the use of internal pillars 145 makes it easier to put the internal plate 17 in place against the central portion 141 in a sealed manner.

As explained above, said at least one housing 13 desirably opens onto at least one lateral face of the cooling module 1 in order to make it possible to laterally insert said at least one electrical module 2 into said at least one housing 13. In particular, said at least one housing 13 can be a through-housing, in other words it opens onto two opposite lateral faces of the cooling module 1. A through-housing advantageously makes it possible to electrically connect said at least one electrical module 2 on either side of the cooling module 1. For example, in the context of an inverter or an electrical charger, one side of said at least one electrical module 2 can comprise connections of AC type while the opposite side of said at least one electrical module 2 can comprise connections of DC type.

Furthermore, the main body 14 preferably consists of a part that is moulded using a conventional moulding technology, in particular sand casting, which is compatible with a high production rate and results in a reduction in the manufacturing cost incurred.

It is recalled that the electrical assembly advantageously comprises the cooling module 1 and said at least one electrical module 2. Said at least one electrical module 2 preferably consists of a plurality of power electronic modules, the number of which corresponds in particular to the number of housings. Thus, the electrical assembly can form part of a power electrical apparatus, in particular of an inverter, a DC-to-DC voltage converter, or an electrical charger, which is configured to be installed on board an electric or hybrid vehicle.

As expressed above, the cooling module 1 according to the invention has four main heat exchange surfaces comprising two internal surfaces and two external surfaces. The two internal surfaces ensure the cooling of said at least one electrical module 2. In addition, the power electrical apparatus can comprise additional electrical components that need to be cooled, in particular a capacitive module. Thus, the two external surfaces of the cooling module 1 can in particular contribute to the cooling by thermal conduction of said additional electrical components.

According to one aspect of the invention, a method for manufacturing the electrical assembly preferably comprises the following successive steps:
moulding and machining the main body 14;
laterally inserting each of said at least one electrical module 2 into each housing of said at least one housing 13;
fastening the internal plate 17 in a sealed manner against the shoulder surface 144 in order to close said at least one housing 13;
fastening the upper plate 15, and the lower plate 16 respectively against the upper external face 142 and the lower external face 143 of the main body 14 so as to respectively form each of the two branches of the cooling channel 11.

In addition, the moulding of the main body 14 can advantageously be realized by way of two half-moulds and a conventional moulding technology.

The technical advantages of the cooling module according to the invention are detailed below.

The cooling module according to the invention has improved cooling effectiveness by offering four heat exchange surfaces, of which two are intended to cool said at least one electrical module on two external faces that are opposite one another. The invention therefore makes it possible for a single portion of the cooling circuit to be shared in order to cool a plurality of electrical components.

The cooling module comprising the two fluid inlet/outlet orifices that are close to one another and open onto the same face of the cooling module makes it easier to position and connect the cooling module with respect to a cooling system external to the cooling module, in particular with respect to the cooling system of the vehicle.

The cooling module according to the invention also has a considerable advantage of reduction in manufacturing costs and compatibility with a high production rate. The configuration of the cooling module, in the form of a stack of various elements, in particular of the main body and the internal, upper and lower plates, makes the processes for manufacturing, assembling, and testing the cooling module easier. More generally, this configuration of the cooling module makes it easier to manufacture the electrical assembly comprising the cooling module.

In addition, the invention has the advantage of being modular and therefore makes it easier to standardize the apparatuses. This also contributes to the implementation of a high production rate, and parallel production lines.

It can also be noted that the invention makes it possible to use power electronic modules that are not sealed, thus reducing the manufacturing costs of the electrical assembly.

The invention makes it possible to perform leak tests on the electrical assembly, independently of other possible electrical components intended to be included in the same power electrical apparatus as the electrical assembly, and in particular a capacitive module.

Thus, if a malfunction of the sealing system was detected, only the electrical assembly would be scrapped. In the prior art, the very design of the power electrical apparatus as described in the preamble does not allow such a test to be performed separately. Therefore, the power electrical apparatus, in the prior art, is tested, in terms of sealing, in its entirety and if a sealing problem is detected, the whole power electrical apparatus has to be scrapped.

Consequently, the present invention has a considerable advantage from the point of view of the industrial production of power electrical apparatuses, in particular inverters, electrical chargers, and DC-to-DC voltage converters, while at the same time making it possible to ensure effective cooling of the electrical components to be cooled.

1. The cooling module, configured to cool at least one electrical module installed on board an electric or hybrid motor vehicle, the cooling module comprising:
two fluid inlet/outlet orifices, for respectively conveying and discharging a cooling fluid into and from the cooling module;
a cooling channel formed in the cooling module
said cooling channel has a U-shaped section forming two branches, the one and the other of the two fluid inlet/outlet orifices respectively terminating in the one and the other of the two branches, such that said cooling channel ensures U-shaped circulation of the cooling fluid between the two fluid inlet/outlet orifices; and
at least one housing between the two branches for allowing the sealed insertion of said at least one electrical module, so as to cool said at least one electrical module by thermal conduction by mechanical contact realized respectively between each branch of the cooling module and two opposite external faces of said at least one electrical module.

2. The according to claim 1, further comprising:
a main body;
an upper plate; and
a lower plate,
the main body having a substantially H-shaped section and comprising a central portion, an upper external face, and a lower external face,
the main body being substantially open on each of the upper external face and lower external face,
the upper plate and the lower plate coming respectively against the upper external face and against the lower external face, such that free volumes respectively delimited by the central portion and the upper plate, and by the central portion and the lower plate, respectively define the one and the other of the two branches of the cooling channel.

3. The cooling module according to claim 2, further comprising an internal plate, wherein the central portion comprises one or a plurality of cutouts formed in the central portion and a shoulder surface coupled to the cutout or the plurality of cutouts, the shoulder surface extending in part around the periphery of the central portion, the internal plate coming to bear against the shoulder surface in a sealed manner so as to form said at least one housing between the central portion and the internal plate.

4. The cooling module according to claim 2, wherein the central portion comprises internal pillars such that said at least one housing comprises a number of housings that are separated from each other by the internal pillars.

5. The cooling module according to claim 2, wherein the main body consists of a part that is moulded by a process of sand casting or high-pressure moulding.

6. The cooling module according to claim 5, wherein the number of housings is equal to three.

7. The cooling module according to claim 1, said at least one housing being a through-housing.

8. An electrical assembly comprising: at least one electrical module; and the cooling module according to claim 1.

9. A power electrical apparatus, in particular configured to be installed on board an electric or hybrid vehicle, comprising: the electrical assembly according to claim 8, said at least one electrical module consisting of a plurality of power electronic modules, said power electrical apparatus forming an inverter, a DC-to-DC voltage converter, or an electrical charger.

10. A method for manufacturing an electrical assembly comprising at least one electrical module and a cooling module comprising a cooling channel having a U-shaped section forming two branches, at least one housing, a main body, an upper plate, a lower plate, and an internal plate, the main body having a substantially H-shaped section and comprising a central portion, an upper external face, and a lower external face, the central portion comprising a shoulder surface, the method comprising the following successive steps:
moulding and machining the main body;
laterally inserting each of said at least one electrical module into each housing of said at least one housing;
fastening the internal plate in a sealed manner against the shoulder surface in order to close said at least one housing; and
fastening the upper plate, and the lower plate respectively against the upper external face and against the lower external face of the main body so as to respectively form each of the two branches of the cooling channel.
